(19) United States
(12) Patent Application Publication
(10) Pub. No.: US 2011/0272829 A1
(43) Pub. Date: Nov. 10, 2011

(54) EPOXY RESIN COMPOSITION FOR OPTICAL-SEMICONDUCTOR ELEMENT ENCAPSULATION AND OPTICAL-SEMICONDUCTOR DEVICE USING THE SAME

(75) Inventors: Kazuhiro FUKE, Osaka (JP); Shinya OTA, Osaka (JP)

(73) Assignee: NITTO DENKO CORPORATION, Osaka (JP)

(21) Appl. No.: 13/100,551

(22) Filed: May 4, 2011

(30) Foreign Application Priority Data
May 10, 2010 (JP) 2010-108352

(51) Int. Cl. H01L 23/29; C08L 63/00

(52) U.S. Cl. 257/793; 525/533; 257/E23.119

(57) ABSTRACT

The present invention relates to an epoxy resin composition for optical-semiconductor element encapsulation, including the following ingredients (A), (B) and (C): (A) an epoxy resin; (B) a curing agent including a phenol resin (b1) represented by the following general formula (1), and an acid anhydride (b2) in which R represents -phenyl- or -biphenyl-, and n is 0 or a positive integer; and (C) a curing accelerator, in which a ratio between the number of hydroxyl groups of the ingredient (b1) and the number of hydroxyl groups of the ingredient (b2), in the ingredient (B) is 99.99/0.01 to 50/50 in terms of b1/b2.

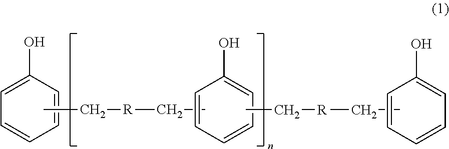

### FIELD OF THE INVENTION

The present invention relates to an epoxy resin composition for optical-semiconductor element encapsulation, which is used for the encapsulation of an optical-semiconductor element, and relates to an optical semiconductor device comprising an optical-semiconductor element resin-encapsulated using the epoxy resin composition.

### BACKGROUND OF THE INVENTION

To an encapsulation material used for encapsulating an optical-semiconductor element such as a light-receiving sensor, light-emitting diode (LED) or a charge-coupled device (CCD), a cured product of the encapsulation material heretofore has been required to have transparency. In general, an acid anhydride type epoxy resin composition obtained by using an epoxy resin and an acid anhydride type curing agent is widely used as the transparent material.

However, in recent years, a surface mounting configuration to a substrate is increased in an optical-semiconductor device with the progress of size reduction of a package. That is, from the fact that mounting in IR reflow is becoming to be used, a transparent encapsulation material having heat resistance and the like higher than the conventional properties is demanded as an epoxy resin composition serving as an encapsulation material of an optical-semiconductor element.

For example, in the above epoxy resin composition for optical-semiconductor element encapsulation, melt-mixing of a biphenyl type epoxy resin with a phenol aralkyl resin is conducted in advance, as a method of improving reliability and adhesion in a thermal stress test such as a temperature cycle test. It has been proposed that an epoxy resin composition is prepared using the pre-mixture and a curing accelerator, and the epoxy resin composition obtained is used as an encapsulation material of an optical-semiconductor element (see Patent Document 1).

Patent Document 1: JP-A-2000-281868

### SUMMARY OF THE INVENTION

Even though the above-described epoxy resin composition is used, it is possible to improve heat resistance and the like to a certain extent. However, soldering resistance serving as reliability at solder reflow is not yet sufficient. In recent years, regarding soldering resistance to an encapsulation material (epoxy resin composition) moisture-absorbed under severer conditions, particularly under high temperature condition, the material requires further excellent soldering resistance, and at the same time, the material is required to have excellent curing property.

The present invention has been made in view of the above circumstances, and has an object to provide an epoxy resin composition for optical-semiconductor element encapsulation, having excellent soldering resistance and curing property as well as good transparency, and an optical-semiconductor device using the same.

Namely, the present invention relates to the following items (1) and (2).

(1) An epoxy resin composition for optical-semiconductor element encapsulation, including the following ingredients (A), (B) and (C):

(A) an epoxy resin;

(B) a curing agent comprising a phenol resin (b1) represented by the following general formula (1), and an acid anhydride (b2);

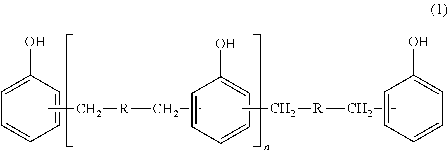

in which R represents -phenyl- or -biphenyl-, and n is 0 or a positive integer; and

(C) a curing accelerator,

in which a ratio between the number of hydroxyl groups of the ingredient (b1) and the number of hydroxyl groups of the ingredient (b2), in the ingredient (B) is 99.99/0.01 to 50/50 in terms of b1/b2.

(2) The epoxy resin composition for optical-semiconductor element encapsulation according to (1), wherein the phenol resin (b1) is a phenol biphenylene resin.

(3) An optical-semiconductor device including an optical-semiconductor element resin-encapsulated with the epoxy resin composition for optical-semiconductor element encapsulation according to (1) or (2).

The present invention diligently made investigations in order to obtain an optical-semiconductor element encapsulation material having excellent soldering resistance under severer conditions, together with good transparency. As a result, they had an idea of a specific combination of a phenol resin (ingredient b1) represented by the above general formula (1) and an acid anhydride (ingredient b2), as a curing agent of an epoxy resin. As a result of further investigations on the idea, they have found that when a curing accelerator (ingredient C) is used together with the above ingredient b1 and ingredient b2 and the ingredient b1 and the ingredient b2 are used in a specific compounding ratio, the improvement in properties of a cured product, represented by, for example, decrease in elastic modulus at a high temperature region is realized, and further excellent soldering resistance is developed at solder reflow, and have reached the present invention.

Thus, the present invention relates to an epoxy resin composition for optical-semiconductor element encapsulation, including an epoxy resin (ingredient A), a curing agent (ingredient B) including a phenol resin (ingredient b1) represented by the general formula (1) and an acid anhydride (ingredient b2) as essential ingredients, and a curing accelerator (ingredient C), in which the ingredient b1 and the ingredient b2 are used in a specific compounding ratio. As a result, the epoxy resin composition has excellent soldering resistance and curing property as well as good light transmittance, at the use wavelength region. Therefore, an optical-semiconductor device having high reliability is obtained by resin-encapsulating an optical-semiconductor element with the epoxy resin composition for optical-semiconductor element encapsulation.

### DETAILED DESCRIPTION OF THE INVENTION

The epoxy resin composition for optical-semiconductor element encapsulation of the present invention (hereinafter referred to as an “epoxy resin composition” for simplicity) is obtained using an epoxy resin (ingredient A), a curing agent (ingredient B) including a specific phenol resin (ingredient b1) and a specific acid anhydride (ingredient b2), as the essential ingredients, and a curing accelerator (ingredient C), and is generally supplied in a liquid state, a powder state or in the form of tablets obtained by tableting the powder.

Examples of the epoxy resin (ingredient A) include bisphenol A epoxy resins, bisphenol F epoxy resins, phenol-novolac epoxy resins, cresol-novolac epoxy resins, alicyclic epoxy resins, nitrogen ring-containing epoxy resins such as triglycidyl isocyanurate and hydantoin epoxy resins, hydrogenated bisphenol A epoxy resins, biphenyl epoxy resins that are the mainstream of low water absorption cured product type, dicyclic epoxy resins, and naphthalene epoxy resins. Those may be used alone or as mixtures of two or more thereof. In general, the epoxy resin having an epoxy equivalent of from 100 to 1,000 and a softening point of 120° C. or lower is preferably used. Of the above various epoxy resins, bisphenol A epoxy resins, bisphenol F epoxy resins, triglycidyl isocyanurate, hydrogenated bisphenol A epoxy resins and aliphatic epoxy resins are preferably used from the standpoint that a cured product of the epoxy resin composition is difficult to discolor after the optical-semiconductor element encapsulation.

The curing agent (ingredient B) used together with the ingredient A includes a specific phenol resin (ingredient b1) and an acid anhydride (ingredient b2) as the essential components. In other words, the curing agent according to the present invention may consist of the essential components of the specific phenol resin (ingredient b1) and the acid anhydride (ingredient b2), and may includes the essential components of the specific phenol resin (ingredient b1) and the acid anhydride (ingredient b2), and other phenol resin.

The specific phenol resin (ingredient b1) means a phenol resin represented by the following general formula (1):

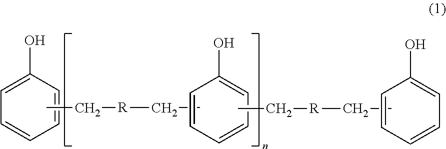

in which R represents -phenyl- or -biphenyl-, and n is 0 or a positive integer.

In the general formula (1), the repeating number n is 0 or a positive integer, and is preferably from 0 to 3. The specific phenol resin having a hydroxyl equivalent ranging from 145 to 567 is preferably used. Of these, a phenol biphenylene resin is preferably used.

The acid anhydride (ingredient b2) concurrently used preferably has a molecular weight of from about 140 to 200. Examples of the acid anhydride (ingredient b2) include colorless or pale yellow acid anhydrides such as phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, methylhexahydrophthalic anhydride and methyltetrahydrophthalic anhydride. Those are used alone or as mixtures of two or more thereof. Of those acid anhydride curing agents, hexahydrophthalic anhydride and methylhexahydrophthalic anhydride each having lower absorption in a short wavelength region are preferably used.

The ratio in the number of hydroxyl group between the number of hydroxyl groups of the specific phenol resin (ingredient b1) and the number of hydroxyl groups of the acid anhydride (ingredient b2) is in a range of 99.99/0.01 to 50/50 in terms of b1/b2, and preferably in a range of 99.95/0.05 to 55/45 in terms of b1/b2. That is, when the compounding ratio of those ingredients are outside the range, for example, the ratio of the specific phenol resin (ingredient b1) exceeds 99.99 and the ratio of the acid anhydride (ingredient b2) is less than 0.01, curing property is deteriorated. On the other hand, when the ratio of the specific phenol resin (ingredient b1) is less than 50 and the ratio of the acid anhydride (ingredient b2) exceeds 50, soldering resistance is deteriorated. The number of hydroxyl groups in the present invention is obtained by dividing the content of the ingredient b1 or the ingredient b2 by the respective hydroxyl equivalent, and the hydroxyl equivalent means a value obtained by dividing the molecular weight of each ingredient by the number of hydroxyl groups in the molecule.

The present invention uses the specific phenol resin and the acid anhydride as essential ingredients of the curing agent (ingredient B). However, as described before, other phenol resin may be added so long as it is a range that does not impair the effect of the present invention. As the other epoxy resin, a compound having two or more phenolic hydroxyl groups which are functional groups capable of reacting with an epoxy resin, in one molecule thereof may be mentioned, and examples thereof include phenol-novolac resins.

The content ratio between the epoxy resin (ingredient A) and the curing agent (ingredient B) including the specific phenol resin and the acid anhydride as the essential ingredients is set such that the hydroxyl equivalent in the curing agent (ingredient B) becomes preferably from 0.5 to 1.5 equivalents, and particularly preferably from 0.7 to 1.2 equivalents, to one equivalent of the epoxy group in the epoxy resin (ingredient A). That is, when the hydroxyl equivalent is less than the lower limit in the above ratio, there is a tendency that the hue of the epoxy resin composition obtained is deteriorated after curing. On the other hand, when the hydroxyl equivalent exceeds the upper limit, there is a tendency that moisture resistance is decreased.

Examples of the curing accelerator (ingredient C) used together with the ingredient A and the ingredient B include tertiary amines, imidazoles, quaternary ammonium salts, organic metal salts and phosphorus compounds. Those are used alone or as mixtures of two or more thereof. Of the above curing accelerators (ingredient C), phosphorus compounds and imidazoles are preferably used, and imidazoles are further preferably used.

The content of the curing accelerator (ingredient C) is in a range of preferably from 0.05 to 7.0 parts by weight (hereinafter referred to as “parts” for simplicity), and more preferably from 0.2 to 3.0 parts, per 100 parts of the epoxy resin (ingredient A). When the content of the curing accelerator is less than the lower limit, there is a tendency that sufficient curing accelerating effect is not achieved. On the other hand, the content thereof exceeds the upper limit, there is a tendency that discoloration appears in a cured product of the epoxy resin composition.

As necessary, other than the ingredients A to C described above, the epoxy resin composition of the present invention can appropriately contain the conventional various additives such as deterioration inhibitors, modifiers, release agents, dyes and pigments in a range that does not impair various properties such as light transmittance of the epoxy resin composition.

Examples of the degradation inhibitors include hindered phenol compounds, amine compounds and organic sulfur compounds. Those may be used alone or as mixtures of two or more thereof. Each compound may use plural kinds.

Examples of the modifiers include glycols, silicones and alcohols. Those may be used alone or as mixtures of two or more thereof.

Examples of the release agents include stearic acid, behenic acid, montanic acid and its metal salt, polyethylene-based wax, polyethylene-polyoxyethylene based wax and carnauba wax. Those may be used alone or as mixtures of two or more thereof. Of those release agents, the polyethylene-polyoxyethylene based wax is preferably used from the standpoint that transparency of a cured product of the epoxy resin composition becomes good.

In the case of requiring light dispersibility, the epoxy resin may further contain fillers in addition to the above ingredients. Examples of the fillers include inorganic fillers such as quartz glass powder, talc, silica powder, alumina powder and calcium carbonates. Those may be used alone or as mixtures of two or more thereof.

The epoxy resin composition of the present invention is produced, for example, as follows, and the form produced is a liquid state, a powder state or tablets obtained by tableting the powder. Specifically, to obtain a liquid epoxy resin composition, the ingredients A to C and as necessary, the conventional various additives such as degradation inhibitors, modifiers, release agents, dyes, pigments and fillers are compounded in the prescribed ratio. To obtain the epoxy resin in a powder state or a tablet state obtained by tableting the powder, the above ingredients are appropriately compounded, followed by pre-mixing. The resulting mixture is mixed and kneaded appropriately using a method such as a dry blend method or a melt blend method. The kneaded mixture is cooled to room temperature, passed through an aging step, pulverized, and if necessary, is subjected to tableting.

The epoxy resin composition thus-obtained of the present invention is used as an encapsulation material of an optical-semiconductor element such as a light-receiving sensor, a light-emitting diode (LED), a charge-coupled device (CCD). Specifically, to encapsulate an optical-semiconductor element using the epoxy resin composition of the present invention, the encapsulation can be carried out by a molding method such as transfer molding or cast molding. In the case that the epoxy resin composition of the present invention is liquid state, the liquid epoxy resin composition is generally used in the form of a so-called two-liquid type such that at least an epoxy resin component and a curing agent component are stored separately and are mixed just before the use. In the case that the epoxy resin composition of the present invention is a powder state or a tablet state, having been passed through a prescribed aging step, it is generally preferred that when melt-mixing the components, it is maintained in a B-stage (semi-cured state), and then, is heat melted at the use.

In the epoxy resin composition of the present invention, its cured product used has light transmittance of from 75 to 99% in a thickness of 1 mm at a wavelength of 650 nm at room temperature by the measurement with a spectrophotometer (product name: V-670, manufactured by JASCO Corporation) from the point of its use as optical-semiconductor encapsulation. The cured product having light transmittance of 90% or more is preferably used. However, the light transmittance in the case of using the above-described fillers, dyes or pigments is not limited to the above. In the present invention, the term “room temperature” means 25° C.±5° C.

The epoxy resin composition of the present invention has a glass transition temperature (Tg) of from 100 to 150° C. as one of the properties of a suitable cured product as an encapsulation material. Furthermore, the epoxy resin composition of the present invention has a storage elastic modulus at the temperature 50° C. higher than the glass transition temperature of from 2 to 15 MPa. Due to those properties, the epoxy resin composition of the present invention has excellent soldering resistance.

### EXAMPLES

Examples are given together with Comparative Examples. However, the present invention should not be construed as being limited to the following Examples.

First, prior to the production of epoxy resin compositions, the ingredients shown below were prepared.

### Epoxy Resin (Ingredient A)

Bisphenol A epoxy resin (epoxy equivalent: 185)

Curing Agent (i) (Ingredient b1)

Phenol resin represented by the following general formula (2):

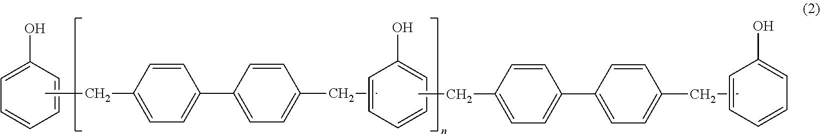

in which n is 1; phenol biphenylene resin, hydroxyl equivalent: 203.
Curing Agent (ii) (Ingredient b1)

Phenol resin represented by the following general formula (3):

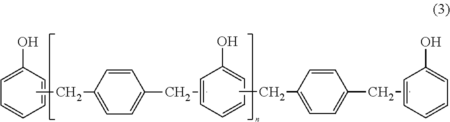

in which n is 1; phenol/p-xylene glycol dimethyl ether polycondensate, hydroxyl equivalent: 172.
Curing Agent (iii) (Ingredient b2)

Hexahydrophthalic anhydride (molecular weight: 154, hydroxyl equivalent: 154)

### Curing Accelerator (Ingredient C)

2-ethyl-4-methyl imidazole

### Examples 1 to 6 and Comparative Examples 1 to 4

The ingredients shown in Table 1 below were compounded together according to each of the formulations shown in Table 1, and melt-kneaded (50 to 150° C.) with a mixing roller. Each mixture was aged, subsequently cooled to room temperature (25° C.), and pulverized. Thus, desired fine powdery epoxy resin compositions were produced.

TABLE 1
(parts by weight)

| | | Example | | | | | | Comparative Example | | | |
|---|---|---|---|---|---|---|---|---|---|---|---|
| | | 1 | 2 | 3 | 4 | 5 | 6 | 1 | 2 | 3 | 4 |
| Epoxy resin | Ingredient A | 100 | 100 | 100 | 100 | 100 | 100 | 100 | 100 | 100 | 100 |
| Curing agent (i) | Ingredient B | 109.0 | 104.0 | 66.2 | 54.0 | — | — | 44.0 | — | 110.0 | 93.0 |
| (Ingredient b1) *1 | | | | | | | | | | | |
| Curing agent (ii) | | — | — | — | — | 92.0 | 48.1 | — | — | — | — |
| (Ingredient b1) *2 | | | | | | | | | | | |
| Curing agent (iii) | | 0.01 | 4.5 | 33.0 | 43.0 | 0.01 | 41.1 | 50.0 | 83.2 | — | — |
| (Ingredient b2) *3 | | | | | | | | | | | |
| Curing | Ingredient C | 1.5 | 1.5 | 1.5 | 1.5 | 1.5 | 1.5 | 1.5 | 1.5 | 1.5 | 1.5 |
| accelerator | | | | | | | | | | | |

| | | | | | | | | | | |
|---|---|---|---|---|---|---|---|---|---|---|
| b1/b2 (Ratio of the number of | 99.99/0.01 | 94.6/5.4 | 60.3/39.7 | 48.8/51.2 | 99.99/0.01 | 51.1/48.9 | 40/60 | 0/100 | 100/0 | 100/0 |
| hydroxyl groups) | | | | | | | | | | |

*1: Phenol biphenylene resin (hydroxyl equivalent: 203)
*2: Phenol/p-xylene glycol dimethyl ether polycondensate (hydroxyl equivalent: 172)
*3: Hexahydrophthalic anhydride (hydroxyl equivalent: 154)

The epoxy resin compositions of Examples and Comparative Examples thus obtained were evaluated for various properties by the following methods. The results are shown in Table 2 given later.

### Glass Transition Temperature (Tg)

Each epoxy resin composition prepared above was molded with an exclusive mold (curing conditions: 150° C.×4 minutes) to prepare a test piece (size: 50 mm diameter, 1 mm thickness) of a cured product. The test piece was heated at 150° C. for 3 hours to completely terminate the curing. The test piece in which the curing had completely been terminated was measured with a differential scanning calorimeter (DSC: DSC-6220, manufactured by Seiko Instruments Inc.), and the intermediate point between two folding points appeared before and after the glass transition temperature was used as a glass transition temperature (° C.).

### Storage Elastic Modulus

Using RSA-II, manufactured by RHEOMETRIC SCIENTIFIC, a test piece of a cured product having a width of 5 mm, a thickness of 1 mm and a length of 35 mm prepared by the same curing conditions (150° C.×4 minutes) as the glass transition temperature test was measured under the measurement conditions of 1 Hz and 10° C./min in a temperature range of from 30 to 270° C., and the storage elastic modulus at the temperature 50° C. higher than the glass transition temperature obtained by above measurement was obtained.

### Soldering Resistance

Using each epoxy resin composition above, an optical-semiconductor element (SiN photodiode: 1.8 mm×2.3 mm×0.25 mm thickness) was molded by transfer molding (molding at 150° C. for 4 minutes, and post-curing at 150° C. for 3 hours) to prepare a surface-mount optical-semiconductor device. The surface-mount optical-semiconductor device is 8 pins small outline package (SOP-8: 4.9 mm×3.9 mm×1.5 mm thickness, lead flame: silver plating layer (thickness 0.5 μm) on the entire surface of 42 alloy material.

Using the SOP-8 package, packages (each 10 samples) passed through three kinds of moisture absorption conditions of (1) not moisture-absorbed (non-moisture absorption condition), (2) moisture absorption condition of 30° C./60 RH %×96 hours, and (3) moisture absorption condition of 30° C./60 RH %×192 hours were subjected to infrared (IR) reflow, respectively, and the proportion that peeling and crack occurred in the package itself was individually measured and evaluated. The case that occurrence probability of package peeling and crack is from 0 to less than 34% was expressed as “Good”, the case that occurrence probability of package peeling and crack is from 34 to less than 67% was expressed as “Fair”, and case that occurrence probability of package peeling and crack is from 67 to 100% was expressed as “Poor”.

TABLE 2

| | | Example | | | | | | Comparative Example | | | |
|---|---|---|---|---|---|---|---|---|---|---|---|
| | | 1 | 2 | 3 | 4 | 5 | 6 | 1 | 2 | 3 | 4 |
| Tg (° C.) | | 115 | 115 | 115 | 115 | 118 | 119 | 115 | 150 | Molding | Molding |
| Storage elastic modulus (MPa) | | 5 | 5 | 9 | 10 | 14 | 15 | 17 | 22 | impossible | impossible |
| Soldering | Non-moisture | Good | Good | Good | Good | Good | Good | Poor | Poor | | |
| resistance | absorption | | | | | | | | | | |
| | 30° C./60 RH | Good | Good | Good | Good | Fair | Fair | Poor | Poor | | |
| | % × 96 hr | | | | | | | | | | |
| | 30° C./60 RH | Good | Good | Good | Good | Fair | Fair | Poor | Poor | | |
| | % × 192 hr | | | | | | | | | | |

Form the results of Table 2 above, the products of Examples 1 to 4 do not substantially generate peeling and crack under all of the conditions of soldering resistance, and good results were obtained. Regarding the products of Examples 5 and 6, peeling and crack slightly occurred under high temperature and high humidity conditions, but the products were durable to the practical use. It is therefore seen that the optical-semiconductor devices obtained using the epoxy resin compositions of the Examples have excellent soldering resistance and excellent reliability.

Contrary to this, the products of Comparative Examples 1 and 2 showed very high ratio of occurrence of peeling and crack, and could not be durable to the practical use. On the other hand, regarding the products of Comparative Examples 3 and 4, since curing of the resin at molding was slow and viscosity of the resin was low, the package for the evaluation of properties could not be obtained.

The cured products of the Examples and the Comparative Examples all had light transmittance of 90% or more.

While the invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2010-108352 filed on May 10, 2010, and the contents are incorporated herein by reference.

All references cited herein are incorporated by reference herein in their entirety.

Also, all the references cited herein are incorporated as a whole.

The epoxy resin composition of the present invention is useful as an encapsulation material used for encapsulating an optical-semiconductor element such as a light-receiving sensor, light-emitting diode (LED) or a charge-coupled device (CCD).

What is claimed is:

1. An epoxy resin composition for optical-semiconductor element encapsulation, comprising the following ingredients (A), (B) and (C):
(A) an epoxy resin;
(B) a curing agent comprising a phenol resin (b1) represented by the following general formula (1), and an acid anhydride (b2); 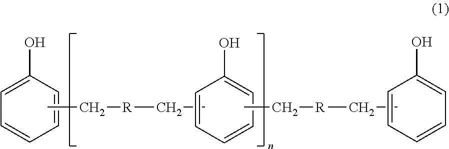
in which R represents -phenyl- or -biphenyl-, and n is 0 or a positive integer; and
(C) a curing accelerator,
wherein a ratio between the number of hydroxyl groups of the ingredient (b1) and the number of hydroxyl groups of the ingredient (b2), in the ingredient (B) is 99.99/0.01 to 50/50 in terms of b1/b2.

2. The epoxy resin composition for optical-semiconductor element encapsulation according to claim 1, wherein the phenol resin (b1) is a phenol biphenylene resin.

3. An optical-semiconductor device comprising an optical-semiconductor element resin-encapsulated with the epoxy resin composition for optical-semiconductor element encapsulation according to claim 1.

4. An optical-semiconductor device comprising an optical-semiconductor element resin-encapsulated with the epoxy resin composition for optical-semiconductor element encapsulation according to claim 2.
